(19) United States
(12) Patent Application Publication
(10) Pub. No.: US 2019/0277918 A1
(43) Pub. Date: Sep. 12, 2019

(54) BATTERY MONITORING DEVICE AND BATTERY MONITORING SYSTEM

(71) Applicants: Kabushiki Kaisha Toshiba, Tokyo (JP); Toshiba Electronic Devices & Storage Corporation, Tokyo (JP)

(72) Inventors: Atsuhisa Suzuki, Yokohama Kanagawa (JP); Katsuo Yamasaki, Chigasaki Kanagawa (JP)

(73) Assignees: Kabushiki Kaisha Toshiba, Minato-ku, Tokyo (JP); Toshiba Electronic Devices & Storage Corporation, Minato-ku, Tokyo (JP)

(21) Appl. No.: 16/125,821

(22) Filed: Sep. 10, 2018

(30) Foreign Application Priority Data
Mar. 6, 2018 (JP) 2018-039654

(51) Int. Cl. G01R 31/36

(52) U.S. Cl. CPC G01R 31/3651; H02J 7/0021

(57) ABSTRACT

According to an embodiment, a battery monitoring device monitors voltage of a battery cell via a first filter circuit connected to both ends of the battery cell and a second filter that is located in a subsequent stage of the first filter circuit and includes a plurality of voltage measurement paths for the battery cell. The battery monitoring device includes a multiplexer to selectively switch a plurality of voltage measurement paths, an AD converter to convert, into a digital signal, an analog signal transmitted on the voltage measurement path selected by the multiplexer, and a digital filter circuit to perform filtering that removes a frequency component higher than a predetermined frequency component, on the digital signal.

### CROSS-REFERENCE TO RELATED APPLICATIONS

This application is based upon and claims the benefit of priority from Japanese Patent Application No. 2018-039654, filed on Mar. 6, 2018; the entire contents of which are incorporated herein by reference.

### FIELD

An embodiment of the present invention relates to a battery monitoring device and a battery monitoring system.

### BACKGROUND

A battery monitoring system is known, which individually monitors voltages of a plurality of battery cells connected in series. Such a battery monitoring system is provided with a filter circuit to remove noise unnecessary for voltage measurement.

In certain applications, such as an automotive application, redundancy in a voltage measurement path is required in preparation for an unexpected situation such as failure. However, it is difficult to form a redundant voltage measurement path having filter characteristics equivalent to a voltage measurement path in a normal state in a filter circuit. Therefore, when measuring voltage of a battery cell on a redundant voltage measurement path, noise may not be satisfactorily attenuated, for example.

An embodiment of the present invention provides a battery monitoring device and a battery monitoring system that are capable of combining redundancy in a voltage measurement path and noise attenuation characteristics.

### BRIEF DESCRIPTION OF THE DRAWINGS

FIG. 1 is a circuit diagram illustrating a configuration of a battery monitoring system according to this embodiment;

FIG. 2 is a block diagram illustrating a configuration of an AD converter; and

FIG. 3 is a circuit diagram illustrating a modification of a first filter circuit.

### DETAILED DESCRIPTION

Embodiments will now be explained with reference to the accompanying drawings. The present invention is not limited to the embodiments.

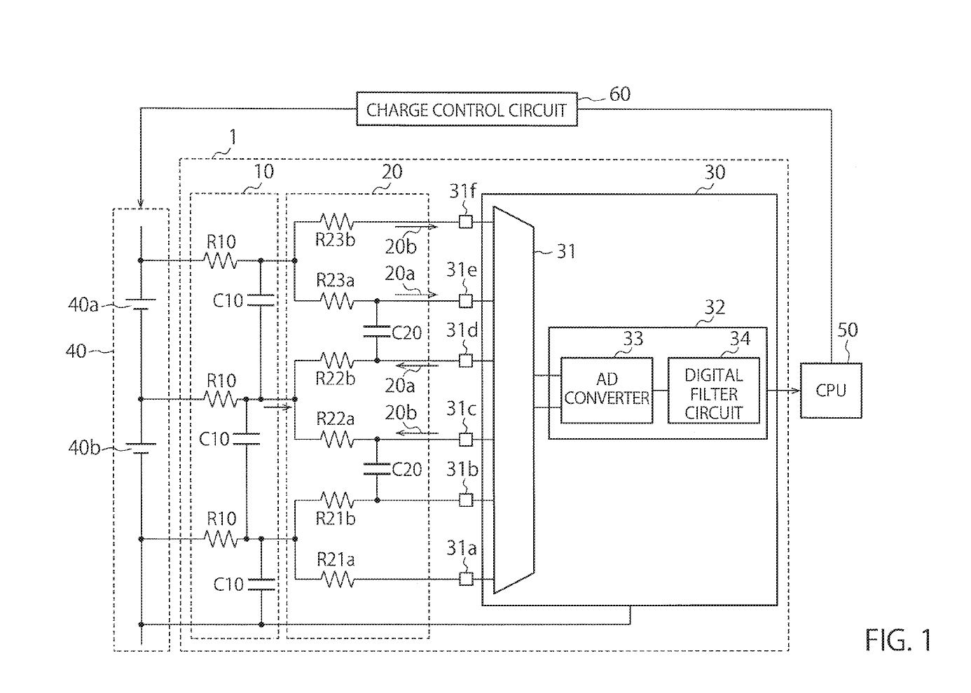

FIG. 1 is a circuit diagram illustrating a configuration of a battery monitoring system according to this embodiment. A battery monitoring system 1 illustrated in FIG. 1 individually monitors voltages of a plurality of battery cells 40a, 40b connected in series within an assembled battery 40. Applicable examples of each battery cell include a lithium-ion battery. In this embodiment, the battery monitoring system 1 is installed in an in-vehicle system. However, the battery monitoring system 1 is not limited to automotive applications and may be applied to, for example, home appliances and robots.

The battery monitoring system 1 includes a first filter circuit 10, a second filter circuit 20, and a battery monitoring device 30. The battery monitoring device 30 has a multiplexer 31 and a voltage measurement unit 32.

The first filter circuit 10 has a plurality of resistors R10 (first resistors) and a plurality of capacitors C10 (first capacitors). One end of each resistors R10 is connected to both ends (positive and negative poles) of each battery cell, whereas the other end of each resistors R10 is connected to the second filter circuit 20. Each capacitor C10 is connected between the other ends of the resistors R10 or between the other end of the corresponding resistor R10 and ground wiring of the battery monitoring device 30. The resistors R10 and the capacitors C10 constitute a so-called n-type filter circuit. The first filter circuit 10 removes a common mode noise with respect to the ground.

The second filter circuit 20 is located in a subsequent stage of the first filter circuit 10. This second filter circuit 20 has a plurality of resistors R21a to R23b (second resistors) and a plurality of capacitors C20 (second capacitors).

One ends of a resistor R2na and a resistor R2nb are commonly connected to the other end of a corresponding one of the resistors R10. Here, “n” is an integer. In addition, each capacitor C20 is connected between other ends of the resistor R2nb and a resistor R2(n+1)a. The resistor R2nb is connected to a lower potential side of the corresponding capacitor C10, and the resistor R(n+1) is connected to a higher potential side of the capacitor C10.

The voltage of the battery cell 40a corresponds to the voltage across the capacitor C20 connected between the resistor R23a and the resistor R22b. Moreover, the voltage of the battery cell 40b corresponds to the voltage across the capacitor C20 connected between the resistor R22a and the resistor R21b.

On the input side of the multiplexer 31, provided is a plurality of terminals 31a to 31f connected to the other ends of the respective resistors R21a to R23b. In the multiplexer 31, a plurality of switches (not shown) connected to the respective terminals are provided. A voltage measurement path of the voltage across each capacitor C20, i.e., the voltage of each battery cell, is selectively switched by switching on and off of the switches in a predetermined order.

For example, the switch connected to the terminal 31d and the switch connected to the terminal 31e are turned on, a voltage measurement path 20a shown in FIG. 1 is selected. Accordingly, the voltage across the capacitor C20 connected between the terminal 31d and the terminal 31e is measured as the voltage of the battery cell 40a in a normal state.

In addition, when it is not possible to select the voltage measurement path 20a due to failure or the like of the resistor R23a, the switch connected to the terminal 31c and the switch connected to the terminal 31f are turned on. In this case, a redundant voltage measurement path 20b is selected to measure the voltage of the battery cell 40a. If the redundant voltage measurement path 20b is selected, filter effect of the second filter circuit 20 may be lost.

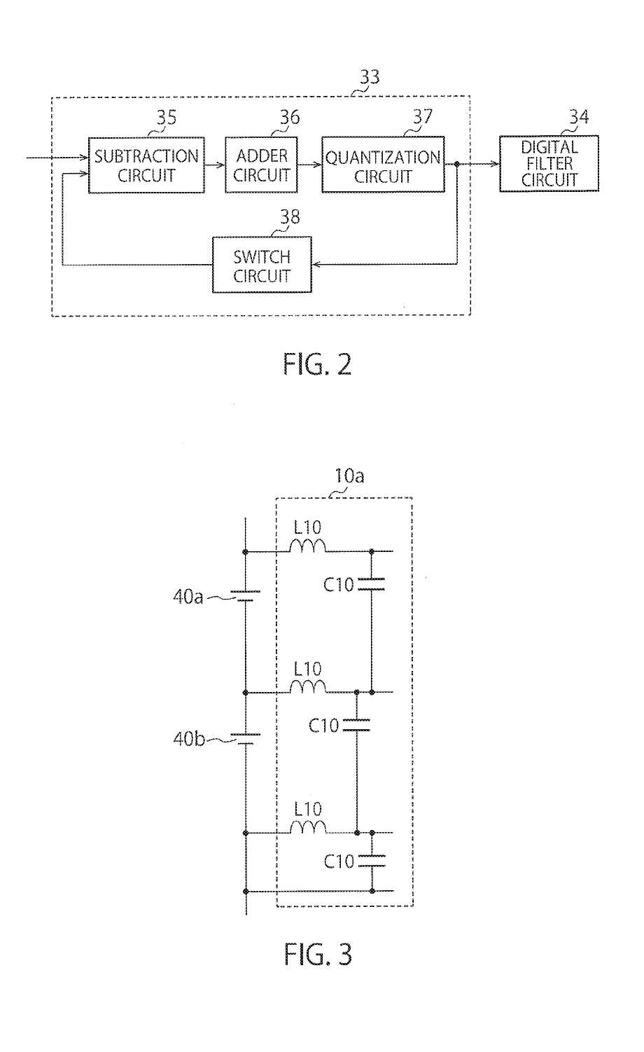

The voltage measurement unit 32 has an AD converter 33 and a digital filter circuit 34. Now, configuration of the AD converter 33 is described with reference to FIG. 2. As illustrated in FIG. 2, the AD converter 33 has a subtraction (Δ) circuit 35 and an adder (Σ) circuit 36, a quantization circuit 37, and a switch circuit 38.

The subtraction circuit 35 subtracts a fixed value set by the switch circuit 38 from a value of an analog signal transmitted on the voltage measurement path selected by the multiplexer 31. The subtraction circuit 35 outputs a result of the calculation to the adder circuit 36.

The adder circuit 36 sequentially adds the result of the calculation by the subtraction circuit 35. Also, the adder circuit 36 outputs a result of the calculation to the quantization circuit 37.

The quantization circuit 37 compares the result of the calculation by the adder circuit 36 with a reference value at a predetermined sampling frequency. In accordance with a result of the comparison, “1” or “0” is output. As a result, the analog signal is quantized and converted into a digital signal.

The switch circuit 38 sets the fixed value in accordance with the result of the comparison in the quantization circuit 37. Specifically, the switch circuit 38 outputs to the subtraction circuit 35, the positive or negative fixed value in accordance with the output of “1, or “0”.

The AD converter 33 of this embodiment is capable of reducing quantization noise. Note that, the configuration of the AD converter 33 is not limited to the circuit diagram shown in FIG. 2 and is sufficient so long as the analog signal input from the multiplexer 31 is converted into the digital signal.

The digital filter circuit 34 performs filtering that removes a frequency component higher than a predetermined frequency (e.g., 1 kHz), on the digital signal input from the quantization circuit 37. In this embodiment, the digital filter circuit 34 performs the filtering by performing moving average processing on the digital signal.

The digital signal filtered by the digital filter circuit 34 is input to a CPU (Central Processing Unit) 50. The CPU 50 outputs a command to a charge control circuit 60 in accordance with a digital signal value. The charge control circuit 60 controls charge of the assembled battery 40 on the basis of the command from the CPU 50.

According to this embodiment described above, the AD converter 33 performs an analog-to-digital conversion before the digital filter circuit 34 performs filtering. Thus, even though the multiplexer 31 selects the redundant voltage measurement path, a noise component contained in a signal indicating the voltage of each battery cell can be satisfactorily attenuated. Consequently, it is possible to combine redundancy in the voltage measurement path and noise attenuation characteristics.

The noise processing is performed on the digital signal entirely by the digital filter circuit 34, and thus, filtering can be uniformly performed on each battery cell.

(Modification)

FIG. 3 is a circuit diagram illustrating a modification of the first filter circuit. A first filter circuit 10a shown in FIG. 3 is different from the first filter circuit 10 in that inductors L10 are provided instead of the resistors R10.

As with the first filter circuit 10, the first filter circuit 10a also constitutes a n-type filter circuit and therefore can remove the common mode noise with respect to the ground.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A battery monitoring device that monitors voltage of a battery cell via a first filter circuit connected to both ends of the battery cell and a second filter circuit located in a subsequent stage of the first filter circuit, the second filter circuit having a plurality of voltage measurement paths for the battery cell, the battery monitoring device comprising:
a multiplexer to selectively switch the plurality of voltage measurement paths;
an AD converter to convert an analog signal transmitted on the voltage measurement path selected by the multiplexer, into a digital signal; and
a digital filter circuit to perform filtering that removes a frequency component higher than a predetermined frequency component, on the digital signal.

2. The battery monitoring device according to claim 1,
wherein the AD converter includes:
a subtraction circuit to output a result of subtracting a value of the analog signal from a fixed value;
an adder circuit to sequentially add the result of the calculation by the subtraction circuit;
a quantization circuit to compare a result of the calculation by the adder circuit with a reference value at a predetermined sampling frequency for quantization; and
a switch circuit to set the fixed value in accordance with a result of the comparison in the quantization circuit.

3. The battery monitoring device according to claim 1,
wherein the digital filter circuit performs moving average processing on the digital signal as the filtering.

4. The battery monitoring device according to claim 2,
wherein the digital filter circuit performs moving average processing on the digital signal as the filtering.

5. The battery monitoring device according to claim 1,
wherein any one of the plurality of voltage measurement paths is a redundant path.

6. A battery monitoring system comprising:
a first filter circuit connected to both ends of a battery cell;
a second filter circuit located in a subsequent stage of the first filter circuit, the second filter circuit having a plurality of voltage measurement paths for the battery cell; and
a battery monitoring device to monitor voltage of the battery cell via the first filter circuit and the second filter circuit,
the battery monitoring device including:
a multiplexer to selectively switch the plurality of voltage measurement paths;
an AD converter to convert, into a digital signal, an analog signal transmitted on the voltage measurement path selected by the multiplexer; and
a digital filter circuit to perform filtering that removes a frequency component higher than a predetermined frequency component, on the digital signal.

7. The battery monitoring system according to claim 6,
wherein the first filter circuit includes a plurality of first resistors having one ends connected to both ends of respective battery cells and other ends connected to the second filter circuit, and a plurality of first capacitors connected between the other ends of the respective first resistors, and
wherein the second filter circuit includes a plurality of second resistors having one ends commonly connected to the other ends of the respective first resistors and other ends connected to an input side of the multiplexer, and a plurality of second capacitors connected between the other ends of respective second resistors connected to higher potential sides of the respective first capacitors and the other ends of the respective second resistors connected to lower potential sides of the respective first capacitors.

8. The battery monitoring system according to claim 7,
wherein the first filter circuit has inductors instead of the first resistors.

9. The battery monitoring system according to claim 6,
wherein the AD converter includes:
a subtraction circuit to output a result of subtracting a value of the analog signal from a fixed value;
an adder circuit to sequentially add the result of the calculation by the subtraction circuit;
a quantization circuit to compare a result of the calculation by the adder circuit with a reference value at a predetermined sampling frequency for quantization; and
a switch circuit to set the fixed value in accordance with a result of the comparison in the quantization circuit.

10. The battery monitoring system according to claim 6,
wherein the digital filter circuit performs moving average processing on the digital signal as the filtering.

11. The battery monitoring system according to claim 6,
wherein any one of the plurality of voltage measurement paths is a redundant path.
